(19) United States
(12) Patent Application Publication
(10) Pub. No.: US 2016/0013305 A1
(43) Pub. Date: Jan. 14, 2016

(54) NITRIDE SEMICONDUCTOR DEVICE AND METHOD FOR MANUFACTURING NITRIDE SEMICONDUCTOR DEVICE

(71) Applicant: SHARP KABUSHIKI KAISHA, Osaka-shi, Osaka (JP)

(72) Inventor: Koichiro FUJITA, Osaka-shi, Osaka (JP)

(73) Assignee: SHARP KABUSHIKI KAISHA, Osaka-shi, Osaka (JP)

(21) Appl. No.: 14/773,094

(22) PCT Filed: Mar. 5, 2014
(86) PCT No.: PCT/JP2014/055595

§ 371 Date: Sep. 4, 2015

(30) Foreign Application Priority Data
Mar. 19, 2013 (JP) 2013-057045

(51) Int. Cl. H01L 29/778; H01L 29/45; H01L 29/66; H01L 21/02; H01L 29/06; H01L 21/283; H01L 21/3213; H01L 21/324; H01L 29/205; H01L 29/20; H01L 29/417; H01L 21/306

(52) U.S. Cl. CPC H01L 29/7787; H01L 29/41758; H01L 29/452; H01L 29/66462; H01L 21/0254; H01L 21/30612; H01L 21/283; H01L 21/32133; H01L 21/324; H01L 29/205; H01L 29/41766; H01L 29/2003; H01L 29/0684

(57) ABSTRACT

A nitride semiconductor device includes a first semiconductor layer disposed on a substrate and made from a nitride semiconductor, a second semiconductor layer stacked on the first semiconductor layer and made from a nitride semiconductor forming a heterointerface, a two-dimensional electron layer disposed at the heterointerface of the first semiconductor layer to the second semiconductor layer, a concave portion which penetrates the second semiconductor layer and reaches part of the first semiconductor layer, and an ohmic electrode, part of which is buried in the concave portion, wherein the angle, on the acute angle side, formed by the heterointerface with the contact surface between the second semiconductor layer and the ohmic electrode is set at 60° or more and 85° or less. In this manner, the contact resistance between the first semiconductor layer and the ohmic electrode is reduced.

### TECHNICAL FIELD

The present invention relates to a nitride semiconductor device and a method for manufacturing a nitride semiconductor device.

### BACKGROUND ART

A semiconductor device, wherein a two-dimensional electron gas formed at a heterointerface between an electron transit layer and an electron supply layer, which are made from different nitride semiconductors, serves as a channel, has been previously disclosed in Japanese Unexamined Patent Application Publication No. 2007-53185 (PTL 1).

In this semiconductor device, an ohmic electrode is arranged in such a way that the end portion thereof on the substrate principal surface side penetrates the electron supply layer from the upper surface of the above-described electron supply layer and reaches a depth deeper than the above-described heterointerface and a depth at which the above-described electron transit layer is not penetrated.

In this manner, the contact resistance between the above-described ohmic electrode and the above-described electron transit layer is reduced as compared with the case where the ohmic electrode is arranged at a depth not reaching the heterointerface.

In addition, in the above-described semiconductor device, the contact resistance between the above-described ohmic electrode and the above-described electron transit layer is further reduced by setting the angle, on the acute angle side, formed by the tangent plane of the surface of the above-described ohmic electrode with a plane in which the above-described heterointerface is extended at an angle of more than 0° and 56° or less.

However, the above-described semiconductor device in the related art disclosed in PTL 1 has a problem that in the case where the ohmic electrode having the above-described structure is formed actually, sufficiently low contact resistance cannot be obtained even when the angle formed by the tangent plane of the surface of the above-described ohmic electrode with the plane in which the above-described heterointerface is extended is more than 0° and 56° or less.

### CITATION LIST

### Patent Literature

PTL 1: Japanese Unexamined Patent Application Publication No. 2007-53185

### SUMMARY OF INVENTION

### Technical Problem

Accordingly, an issue of the present invention is to provide a nitride semiconductor device and a method for manufacturing a nitride semiconductor device, wherein the contact resistance between the ohmic electrode and the nitride semiconductor layer can be reduced.

### Solution to Problem

In order to solve the above-described issue, a nitride semiconductor device according to the present invention includes

a substrate,

a first semiconductor layer disposed on the above-described substrate and made from a nitride semiconductor,

a second semiconductor layer stacked on the above-described first semiconductor layer and made from a nitride semiconductor forming a heterointerface with the above-described first semiconductor layer,

a two-dimensional electron layer which is a layer of a two-dimensional electron gas disposed at the heterointerface of the above-described first semiconductor layer to the above-described second semiconductor layer,

a concave portion disposed in such a way as to penetrate the above-described second semiconductor layer and reach part of the upper side of the above-described first semiconductor layer, and

an ohmic electrode, at least part of which is buried in the above-described concave portion,

wherein the angle, on the acute angle side, formed by the above-described heterointerface with the contact surface between the above-described second semiconductor layer and the above-described ohmic electrode, part of which is buried in the above-described concave portion, is set at 60° or more and 85° or less.

Also, in a nitride semiconductor device according to an embodiment, the angle, on the acute angle side, formed by the above-described heterointerface with the contact surface between the above-described second semiconductor layer and the above-described ohmic electrode is set at 60° or more and 75° or less.

Also, in a nitride semiconductor device according to an embodiment,

the angle, on the acute angle side, formed by the above-described heterointerface with the contact surface between the above-described second semiconductor layer and the above-described ohmic electrode is set at 60° or more and 70° or less.

Also, in a nitride semiconductor device according to an embodiment,

the above-described ohmic electrode is a stacked metal film of TiAl based material in which at least a Ti layer and an Al layer are stacked in this order from the above-described substrate side.

Also, a method for manufacturing a nitride semiconductor device, according to the present invention, includes the steps of

forming a nitride semiconductor layer by stacking a first semiconductor layer made from a nitride semiconductor and a second semiconductor layer made from a nitride semiconductor which forms a heterointerface with the above-described first semiconductor layer sequentially on a substrate,

forming a concave portion, which penetrates the above-described second semiconductor layer and reaches part of the upper side of the above-described first semiconductor layer, through etching,

forming a metal film made from a TiAl based material on the above-described nitride semiconductor layer through sputtering,

forming an ohmic electrode, at least part of which is buried in the above-described concave portion, through etching of the above-described metal film, and

subjecting the above-described substrate provided with the above-described ohmic electrode to annealing,

wherein in the forming of the above-described concave portion, the angle, on the acute angle side, formed by the above-described heterointerface with the side wall of the above-described concave portion is set at 60° or more and 85° or less.

### Advantageous Effects of Invention

As is clear from the above description, in the nitride semiconductor device or the method for manufacturing a nitride semiconductor device, according to the present invention, the angle, on the acute angle side, formed by the heterointerface between the above-described first semiconductor layer and the above-described second semiconductor layer with the contact surface between the above-described second semiconductor layer and the above-described ohmic electrode, part of which is buried in the above-described concave portion, is set at 60° or more and 85° or less. Therefore, the contact resistance between the nitride semiconductor layer including the above-described first semiconductor layer and the above-described ohmic electrode can be reduced.

### BRIEF DESCRIPTION OF DRAWINGS

FIG. 1 is a sectional view of a nitride semiconductor device according to the present invention.

FIG. 2 is a sectional view in one step of the method for manufacturing a nitride semiconductor device, according to the present invention.

FIG. 3 is a sectional view in a step following the step shown in FIG. 2.

FIG. 4 is a sectional view in a step following the step shown in FIG. 3.

FIG. 5 is a sectional view in a step following the step shown in FIG. 4.

FIG. 6 is a sectional view in a step following the step shown in FIG. 5.

FIG. 7 is a diagram showing the relationship between the recess angle and the contact resistance value.

FIG. 8 is a diagram showing the relationship between the recess angle and the wafer in-plane variation in the contact resistance.

FIG. 9 is a diagram showing the relationship between the recess angle and the lot-to-lot variation in the contact resistance.

### DESCRIPTION OF EMBODIMENTS

The present invention will be described below in detail with reference to the embodiments shown in the drawings.

### First Embodiment

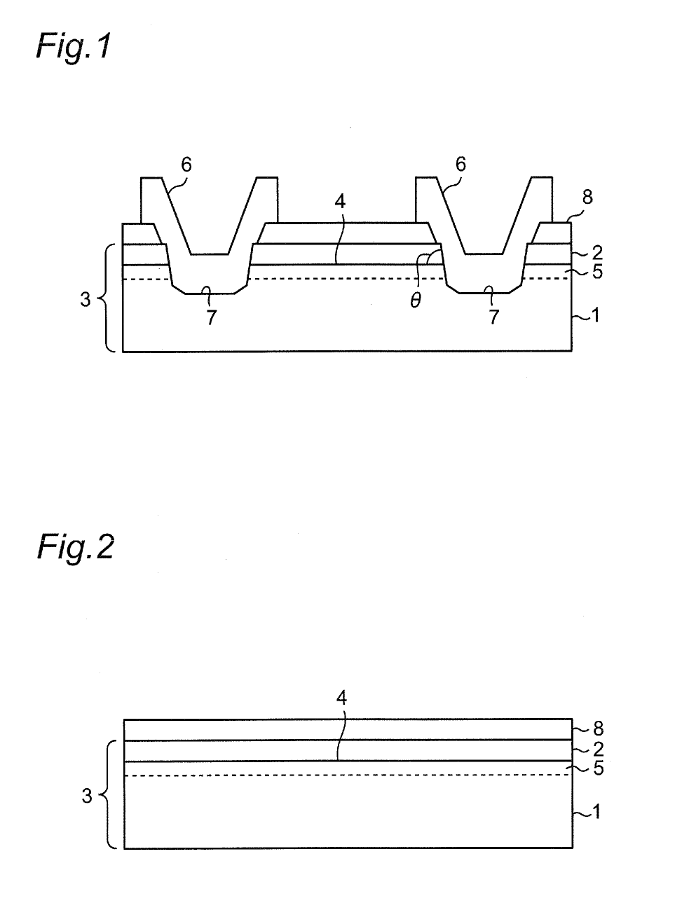

FIG. 1 is a sectional view of a nitride semiconductor device according to the present embodiment.

As shown in FIG. 1, in this nitride semiconductor device, a nitride semiconductor layer 3 is disposed by stacking an undoped GaN layer 1 as an example of the above-described first semiconductor layer and an undoped AlGaN layer 2 as an example of the above-described second semiconductor layer on a Si substrate (not shown in the drawing). In that case, a two-dimensional electron layer 5, that is, a layer in which 2DEG (two-dimensional electron gas) is distributed, is generated at the heterointerface 4 of the undoped GaN layer 1 to the undoped AlGaN layer 2.

In this regard, a buffer layer may be disposed between the above-described Si substrate and the undoped GaN layer (first semiconductor layer) 1. Alternatively, a hetero-improving layer may be disposed between the undoped GaN layer (first semiconductor layer) 1 and the undoped AlGaN layer (second semiconductor layer) 2.

Two ohmic electrodes 6 are disposed apart from each other on the above-described AlGaN layer 2. In that case, a concave portion 7 which penetrates the AlGaN layer 2 serving as an electron supply layer and which reaches part of the upper portion of the GaN layer 1 serving as an electron transit layer is formed in the place to be provided with the ohmic electrode 6 of the AlGaN layer 2. Here, this concave portion 7 is referred to as an ohmic recess portion 7. Then, a structure in which at least part of the ohmic electrode 6 is buried in the ohmic recess portion 7 is employed.

In that case, the angle θ, on the acute angle side, formed by the above-described heterointerface 4 with the contact surface between the AlGaN layer 2 and the ohmic electrode 6 buried in the ohmic recess portion 7 is set at 60° or more and 85° or less.

In addition, an insulating film 8 made from SiN is disposed on the AlGaN layer 2 excluding the region provided with the above-described ohmic electrode 6 in order to protect the AlGaN layer 2. In this regard, the insulating film 8 is not limited to SiN and may be made from SiO₂, Al₂O₃, or the like.

A method for manufacturing the nitride semiconductor device having the above-described configuration will be described below with reference to FIG. 2 to FIG. 6.

Initially, as shown in FIG. 2, an undoped AlGaN buffer layer (not shown in the drawing), the undoped GaN layer 1, and the undoped AlGaN layer 2 are formed sequentially on a Si substrate (not shown in the drawing) by a MOCVD (metal organic chemical vapor deposition) method. In that case, the thickness of the undoped GaN layer 1 is specified to be, for example, 1 μm, and the thickness of the undoped AlGaN layer 2 is specified to be, for example, 30 nm. These GaN layer 1 and the AlGaN layer 2 constitute a nitride semiconductor layer 3.

Subsequently, the insulating film 8 (for example, SiN) having a film thickness of 200 nm is formed on the above-described AlGaN layer 2 by, for example, a plasma CVD (chemical vapor deposition) method. In FIG. 2, reference numeral 5 denotes a two-dimensional electron layer which is a layer of two-dimensional electron gas (2DEG) formed at the heterointerface 4 of the GaN layer 1 to the AlGaN layer 2.

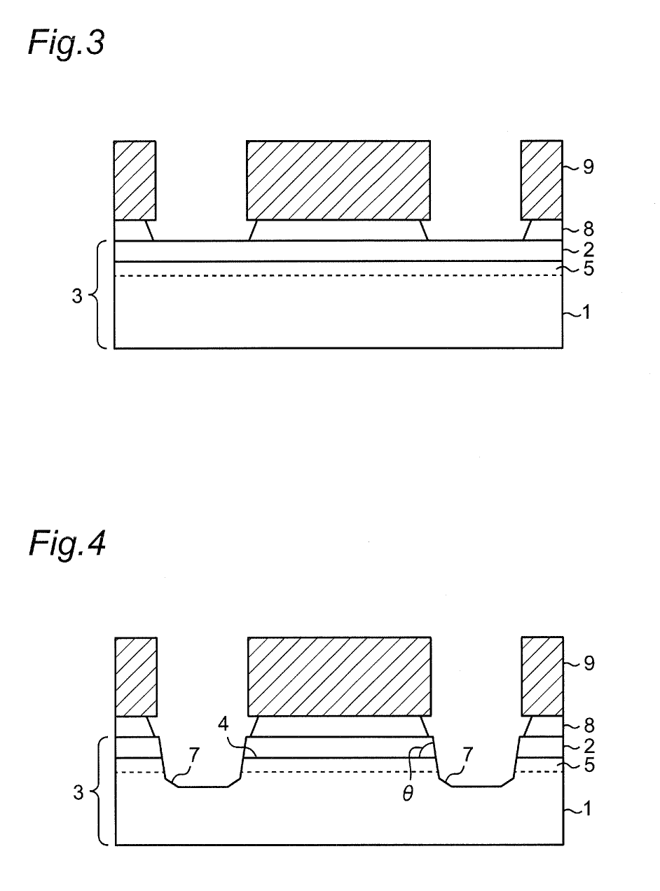

Next, as shown in FIG. 3, a photoresist 9 is applied on the above-described insulating film 8 and patterning is performed. Thereafter, the insulating film 8 in the regions to be provided with ohmic electrodes is removed through wet etching.

Next, as shown in FIG. 4, the resist pattern 9 formed in FIG. 3 is used, and the portions to be provided with the ohmic electrodes of the nitride semiconductor layer 3 are removed through dry etching, so that the ohmic recess portions 7 which penetrate the AlGaN layer 2 and reach part of the upper portion of the GaN layer 1 are formed. Here, the depth of the ohmic recess portion 7 is specified to be at least the depth from the surface of the AlGaN layer 2 to a concentration peak of 2DEG in the two-dimensional electron layer 5 and be, for example, 50 nm.

In that case, the angle θ, on the acute angle side, formed by the above-described heterointerface 4 with the side wall of the ohmic recess portion 7 is specified to be 60° or more and 85° or less. This angle control can be performed by adjusting the dry etching condition (gas composition, gas pressure, plasma generation condition, and the like) to control the anisotropy of etching.

After the above-described resist pattern 9 is removed, annealing is performed at a temperature of, for example, 500° C. to 850° C.

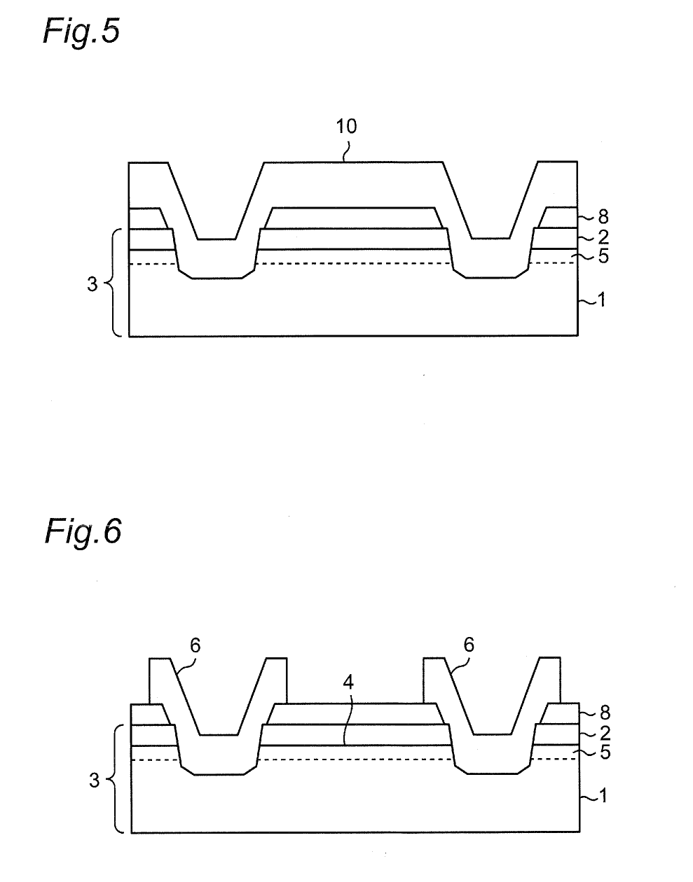

Next, as shown in FIG. 5, Ti/Al/TiN is stacked on the above-described insulating film 8 and in the ohmic recess portions 7 through sputtering to form a stacked metal film 10 serving as the ohmic electrode. Here, the above-described TiN layer is a cap layer to protect the above-described Ti/Al layer from the downstream steps.

In this regard, the oxygen concentration in the resulting ohmic electrode 6 is specified to be 1×10¹⁶ cm⁻³ or more and 1×10²⁰ cm⁻³ or less by passing oxygen in a chamber during sputtering of the above-described Ti layer in the sputtering of the above-described stacked metal film 10. Alternatively, after the sputtering of the above-described Ti layer in the sputtering of the above-described stacked metal film 10, the oxygen concentration in the resulting ohmic electrode 6 is specified to be 1×10¹⁶ cm⁻³ or more and 1×10²⁰ cm ⁻³ or less by subjecting the surface of the Ti layer to an oxygen plasma treatment. Alternatively, the oxygen concentration in the resulting ohmic electrode 6 may be specified to be 1×10¹⁶ cm⁻³ or more and 1×10²⁰ cm⁻³ or less by passing oxygen in a chamber before sputtering of the stacked metal film 10. In this manner, the contact resistance between the undoped GaN layer 1 of the nitride semiconductor layer 3 and the ohmic electrode 6 can be further reduced.

Next, as shown in FIG. 6, the above-described stacked metal film 10 is subjected to common photolithography and dry etching to form the pattern of the ohmic electrode 6. In that case, in a desirable structure, part of the ohmic electrode 6 is extended to the upper surface of the undoped AlGaN layer 2 (second semiconductor layer).

In the case where a field effect transistor (HEMT) is formed by the present nitride semiconductor device, any one of the two ohmic electrodes 6 serves as a source electrode (not shown in the drawing) and the other serves as a drain electrode (not shown in the drawing). In that case, if part of the ohmic electrode 6 is not extended to the upper surface of the undoped AlGaN layer 2 in the structure, the depletion of the two-dimensional electron layer 5 is facilitated by a high electric field at the ohmic electrode 6 which functions as the above-described drain electrode, so that an increase in contact resistance is caused. In the structure according to the present invention, the ohmic electrode 6 is extended to the upper surface of the undoped AlGaN layer 2 by a length of about 0.25 μm.

Then, ohmic contact between the two-dimensional electron layer 5 and the ohmic electrode 6 is obtained by annealing the substrate provided with the above-described ohmic electrode 6 at a temperature of, for example, 400° C. or higher and 500° C. or lower for 10 minutes or more. In that case, the contact resistance can be reduced considerably as compared with the case where the annealing is performed at a temperature higher than 500° C. In addition, the annealing at a low temperature of 400° C. or higher and 500° C. or lower does not adversely affect the characteristics of the insulating film 8.

As described above, in the case where the field effect transistor is formed by the present nitride semiconductor device, the two ohmic electrodes 6 serve as the above-described source electrode and the above-described drain electrode, and a gate electrode (not shown in the drawing) made from TiN, WN, or the like is formed between the two ohmic electrodes 6 in a downstream step.

As described above, according to the method for manufacturing a nitride semiconductor device, in the present embodiment, the angle θ, on the acute angle side, formed by the above-described heterointerface 4 with the side wall of the ohmic recess portion 7 can be specified to be 60° or more and 85° or less, and the angle θ, on the acute angle side, formed by the heterointerface 4 with the contact surface between the AlGaN layer 2 and the ohmic electrode 6 can be set at 60° or more and 85° or less. Consequently, the contact resistance between the undoped GaN layer 1 of the nitride semiconductor layer 3 and the ohmic electrode 6 after the above-described annealing can be reduced.

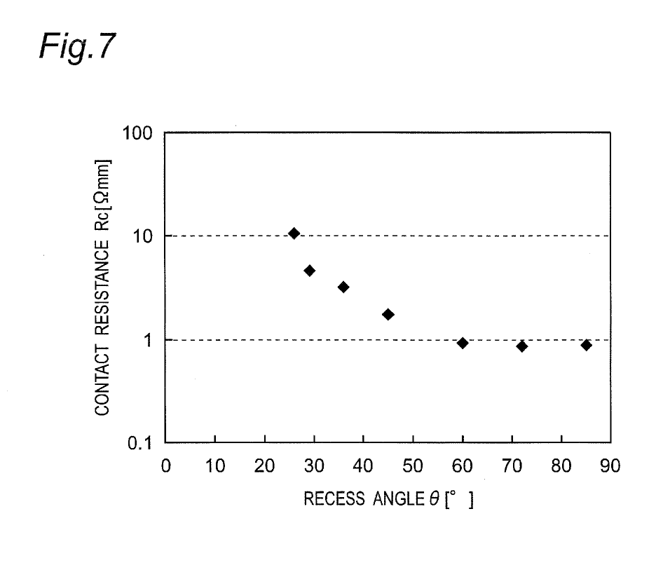

The present inventors examined the relationship between the above-described angle (recess angle) θ and the above-described contact resistance value in the case where the angle θ, on the acute angle side, formed by the above-described heterointerface 4 with the side wall of the ohmic recess portion 7 was set at various angles by adjusting the above-described dry etching condition. The results thereof are shown in FIG. 7. In FIG. 7, the vertical axis indicates the above-described contact resistance Rc [Ωmm]and the horizontal axis indicates the recess angle θ[°].

As is clear from FIG. 7, in the case where the angle (recess angle) θ, on the acute angle side, formed by the above-described heterointerface 4 with the side wall of the ohmic recess portion 7 is specified to be 60° or more and 85° or less, the above-described contact resistance Rc can be reduced to 1 Ωmm or less.

There are uncertain points with respect to the mechanism of the ohmic contact of the nitride semiconductor device. However, it is considered that the results shown in FIG. 7 are obtained for the following reasons, for example.

That is, in the case where the above-described recess angle θ is specified to be 60° or more and 85° or less, the inclination of the side wall of the ohmic recess portion 7 is steep. Therefore, in the vicinity of the contact between the undoped AlGaN layer 2 (second semiconductor layer) and the above-described Ti/Al/TiN (ohmic metal), the thickness of the undoped AlGaN layer 2 is from the heterointerface 4 to the upper surface of the undoped AlGaN layer 2.

On the other hand, in the case where the above-described recess angle θ is specified to be less than 60°, the inclination of the side wall of the ohmic recess portion 7 is gentle. Therefore, in the vicinity of the contact between the undoped AlGaN layer 2 and the above-described Ti/Al/TiN, the thickness of the undoped AlGaN layer 2 is from the heterointerface 4 to the contact surface with the above-described Ti/Al/TiN (inclined surface).

As a result, it is considered that in the case where the above-described recess angle θ was specified to be 60° or more and 85° or less, the thickness of the undoped AlGaN layer 2 was able to be increased in the vicinity of the contact between the undoped A1GaN layer 2 and the above-described Ti/Al/TiN (ohmic metal), the electron gas concentration in the two-dimensional electron layer 5 was thereby increased, and the contact resistance was able to be reduced.

### Second Embodiment

In the present embodiment, when the ohmic recess portion 7 is formed in the step to form the ohmic recess portion 7, shown in FIG. 4, of the above-described first embodiment, the above-described recess angle θ, which is the angle, on the acute angle side, formed by the heterointerface 4 with the side wall of the ohmic recess portion 7, is specified to be 60° or more and 75° or less. In this regard, other steps are the same as those in the case of the above-described first embodiment.

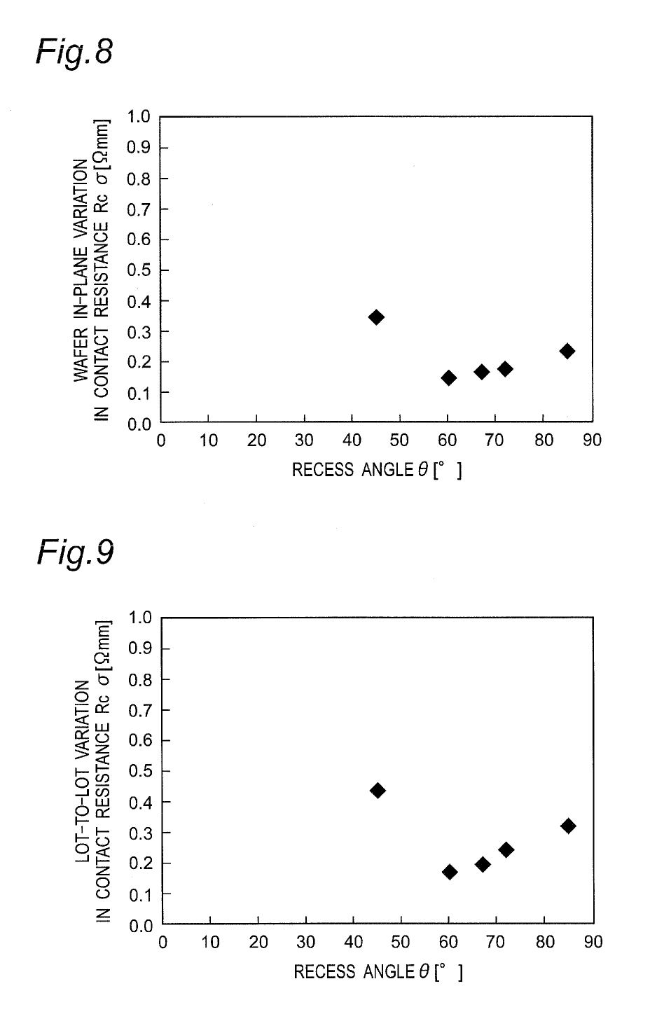

The present inventors examined the relationship between the above-described recess angle θ and the wafer in-plane variation in the contact resistance Rc σ in the case where the above-described recess angle θ was set at various angles by adjusting the dry etching condition (gas composition, gas pressure, plasma generation condition, and the like). The results thereof are shown in FIG. 8.

As is clear from FIG. 8, in the case where the above-described recess angle θ is specified to be 60° or more and 75° or less, the wafer in-plane variation in the contact resistance Rc σ can be reduced to ±0.2 Ωmm or less. That is, as in the present embodiment, it is effective in reducing the wafer in-plane variation in the contact resistance Rc σ to specify the recess angle θ to be particularly 60° or more and 75° or less.

### Third Embodiment

In the present embodiment, when the ohmic recess portion 7 is formed in the step to form the ohmic recess portion 7, shown in FIG. 4, of the above-described first embodiment, the above-described recess angle θ is specified to be 60° or more and 70° or less. In this regard, other steps are the same as those in the case of the above-described first embodiment.

The present inventors examined the relationship between the above-described recess angle θ and the lot-to-lot variation in the contact resistance Rc σ in the case where the above-described recess angle θ was set at various angles by adjusting the dry etching condition (gas composition, gas pressure, plasma generation condition, and the like). The results thereof are shown in FIG. 9.

As is clear from FIG. 9, in the case where the above-described recess angle θ is specified to be 60° or more and 70° or less, the lot-to-lot variation in the contact resistance Rc σ can be reduced to ±0.2 Ωmm or less. That is, as in the present embodiment, it is effective in reducing the lot-to-lot variation in the contact resistance Rc σ to specify the recess angle θ to be particularly 60° or more and 70° or less.

In this regard, in the methods for manufacturing a nitride semiconductor device, according to the above-described first to third embodiments, the regions to be provided with the ohmic electrodes 6 in the above-described insulating film 8 are removed through wet etching. However, the present invention is not limited to this. The ohmic recess portions 7 may be formed by removing the regions to be provided with the ohmic electrodes in the insulating film 8 through dry etching and, thereafter, removing the AlGaN layer 2 and the GaN layer 1 in the regions to be provided with the ohmic electrodes through dry etching.

Also, in the methods for manufacturing a nitride semiconductor device, according to the above-described first to third embodiments, the ohmic electrode 6 is formed by stacking the above-described Ti/Al/TiN. However, the present invention is not limited to this, and the TiN layer may be unnecessary. Alternatively, the above-described Ti/Al may be stacked and, thereafter, Au, Ag, Pt, or the like may be stacked thereon.

Also, in the above-described first to third embodiments, the nitride semiconductor devices by using the above-described Si substrate are explained, although not limited to the Si substrate, and a sapphire substrate or a SiC substrate may be used. Meanwhile, the nitride semiconductor layer may be grown on the sapphire substrate or the SiC substrate. The nitride semiconductor layer may be grown on a substrate made from a nitride semiconductor as in the case where, for example, the AlGaN layer is grown on the GaN substrate. Also, a buffer layer may be formed between the substrate and the nitride semiconductor layer, or a hetero-improving layer may be formed between the undoped GaN layer (first semiconductor layer) 1 and the undoped AlGaN layer (second semiconductor layer) 2 in the nitride semiconductor layer 3.

Meanwhile, it is desirable that the nitride semiconductor in the nitride semiconductor devices according to the above-described first to third embodiments have a composition represented by AlₓIn_{y}Ga_{1-x-y}N (x≦0, y≦0, 0≦x+y≦1).

As described above, in each of the above-described embodiments, the specific embodiment of the present invention has been explained. However, the present invention is not limited to the above-described embodiments and various modification can be made within the scope of the present invention.

As described above, the nitride semiconductor device according to the present invention includes

the substrate,

the first semiconductor layer 1 disposed on the above-described substrate and made from the nitride semiconductor,

the second semiconductor layer 2 stacked on the above-described first semiconductor layer 1 and made from the nitride semiconductor forming the heterointerface 4 with the above-described first semiconductor layer 1,

the two-dimensional electron layer 5 which is the layer of the two-dimensional electron gas disposed at the heterointerface 4 of the above-described first semiconductor layer 1 to the above-described second semiconductor layer 2,

the concave portion 7 disposed in such a way as to penetrate the above-described second semiconductor layer 2 and reach part of the upper side of the above-described first semiconductor layer 1, and

the ohmic electrode 6, at least part of which is buried in the above-described concave portion 7,

wherein the angle, on the acute angle side, formed by the above-described heterointerface 4 with the contact surface between the above-described second semiconductor layer 2 and the above-described ohmic electrode 6, part of which is buried in the above-described concave portion 7, is set at 60° or more and 85° or less.

According to the above-described configuration, the angle, on the acute angle side, formed by the heterointerface 4 between the above-described first semiconductor layer 1 and the second semiconductor layer 2 with the contact surface between the above-described second semiconductor layer 2 and the above-described ohmic electrode 6, part of which is buried in the above-described concave portion 7, is set at 60° or more and 85° or less. Therefore, as shown in FIG. 7, the contact resistance between the above-described first semiconductor layer 1 and the above-described ohmic electrode 6 can be reduced.

Also, in the nitride semiconductor device according to an embodiment,

the angle, on the acute angle side, formed by the above-described heterointerface 4 with the contact surface between the above-described second semiconductor layer 2 and the above-described ohmic electrode 6 is set at 60° or more and 75° or less.

According to this embodiment, the above-described angle θ is set at 60° or more and 75° or less and, thereby, the wafer in-plane variation in the contact resistance between the above-described first semiconductor layer 1 and the above-described ohmic electrode 6 can be reduced to ±0.2 Ωmm or less.

Also, in the nitride semiconductor device according to an embodiment,

the angle, on the acute angle side, formed by the above-described heterointerface 4 with the contact surface between the above-described second semiconductor layer 2 and the above-described ohmic electrode 6 is set at 60° or more and 70° or less.

According to this embodiment, the above-described angle θ is set at 60° or more and 70° or less and, thereby, the lot-to-lot variation in the contact resistance between the above-described first semiconductor layer 1 and the above-described ohmic electrode 6 can be reduced to ±0.2 Ωmm or less.

Also, in the nitride semiconductor device according to an embodiment,

the above-described ohmic electrode 6 is a stacked metal film of TiAl based material in which at least a Ti layer and an Al layer are stacked in this order from the above-described substrate side.

According to this embodiment, the oxygen concentration in the above-described ohmic electrode 6 can be specified to be 1×10¹⁶cm⁻³ or more and 1×10²⁰cm⁻³ or less by supplying oxygen during formation of the above-described Ti layer, after formation of the above-described Ti layer, or before formation of the above-described Ti layer at the time of formation of the above-described ohmic electrode 6 composed of the stacked metal film of the TiAl based material. Therefore, the contact resistance between the above-described first semiconductor layer 1 and the above-described ohmic electrode 6 can be further reduced.

Also, the method for manufacturing a nitride semiconductor device, according to the present invention, includes the steps of

forming the nitride semiconductor layer by stacking the first semiconductor layer 1 made from the nitride semiconductor and the second semiconductor layer 2 made from the nitride semiconductor which forms the heterointerface 4 with the above-described first semiconductor layer 1 sequentially on the substrate,

forming the concave portion 7, which penetrates the above-described second semiconductor layer 2 and reaches part of the upper side of the above-described first semiconductor layer 1, through etching,

forming the metal film 10 made from the TiAl based material on the above-described nitride semiconductor layer through sputtering,

forming the ohmic electrode 6, at least part of which is buried in the above-described concave portion 7, through etching of the above-described metal film 10, and

subjecting the above-described substrate provided with the above-described ohmic electrode 6 to annealing,

wherein in the forming of the above-described concave portion 7, the angle, on the acute angle side, formed by the above-described heterointerface 4 with the side wall of the above-described concave portion 7 is set at 60° or more and 85° or less.

According to the above-described configuration, the angle, on the acute angle side, formed by the above-described heterointerface 4 between the above-described first semiconductor layer 1 and the second semiconductor layer 2 with the side wall of the above-described concave portion 7 is set at 60° or more and 85° or less. Therefore, the angle, on the acute angle side, formed by the above-described heterointerface 4 with the contact surface between the above-described second semiconductor layer 2 and the above-described ohmic electrode 6 can be specified to be 60° or more and 85° or less. As a result, the contact resistance between the above-described first semiconductor layer 1 and the above-described ohmic electrode 6 can be reduced.

### REFERENCE SIGNS LIST

1 undoped GaN layer (first semiconductor layer)

2 undoped AlGaN layer (second semiconductor layer)

3 nitride semiconductor layer

4 heterointerface

5 two-dimensional electron layer

6 ohmic electrode

7 ohmic recess portion

8 insulating film

9 photoresist

10 stacked metal film

1. A nitride semiconductor device comprising:
a substrate;
an undoped first semiconductor layer disposed on the substrate and made from a nitride semiconductor;
an undoped second semiconductor layer stacked on the first semiconductor layer and made from a nitride semiconductor forming a heterointerface with the first semiconductor layer;
a two-dimensional electron layer which is a layer of a two-dimensional electron gas disposed at the heterointerface of the first semiconductor layer to the second semiconductor layer;
a concave portion disposed in such a way as to penetrate the second semiconductor layer and reach part of an upper side of the first semiconductor layer; and
an ohmic electrode, at least part of which is buried in the concave portion,
wherein an angle, on an acute angle side, formed by the heterointerface with a contact surface between the second semiconductor layer and the ohmic electrode, part of which is buried in the concave portion, is set at 60° or more and 85° or less.

2. The nitride semiconductor device according to claim 1,
wherein the angle, on the acute angle side, formed by the heterointerface with the contact surface between the second semiconductor layer and the ohmic electrode is set at 60° or more and 75° or less.

3. The nitride semiconductor device according to claim 1,
wherein the angle, on the acute angle side, formed by the heterointerface with the contact surface between the second semiconductor layer and the ohmic electrode is set at 60° or more and 70° or less.

4. The nitride semiconductor device according to claim 1,
wherein the ohmic electrode is a stacked metal film of TiAl based material in which at least a Ti layer and an Al layer are stacked in this order from a substrate side.

5. A method for manufacturing a nitride semiconductor device, comprising the steps of:
forming a nitride semiconductor layer by stacking an undoped first semiconductor layer made from a nitride semiconductor and an undoped second semiconductor layer made from a nitride semiconductor which forms a heterointerface with the first semiconductor layer, sequentially on a substrate;
forming a concave portion, which penetrates the second semiconductor layer and reaches part of an upper side of the first semiconductor layer, through etching;
forming a metal film made from a TiAl based material on the nitride semiconductor layer through sputtering;
forming an ohmic electrode, at least part of which is buried in the concave portion, through etching of the metal film; and
subjecting the substrate provided with the ohmic electrode to annealing,
wherein in the forming of the concave portion, an angle, on an acute angle side, formed by the heterointerface with a side wall of the concave portion is set at 60° or more and 85° or less.

6. The nitride semiconductor device according to claim 2,
wherein the angle, on the acute angle side, formed by the heterointerface with the contact surface between the second semiconductor layer and the ohmic electrode is set at 60° or more and 70° or less.

7. The nitride semiconductor device according to claim 2,
wherein the ohmic electrode is a stacked metal film of TiAl based material in which at least a Ti layer and an Al layer are stacked in this order from a substrate side.

8. The nitride semiconductor device according to claim 3,
wherein the ohmic electrode is a stacked metal film of TiAl based material in which at least a Ti layer and an Al layer are stacked in this order from a substrate side.
